(19) United States
(12) Patent Application Publication
(10) Pub. No.: US 2013/0049873 A1
(43) Pub. Date: Feb. 28, 2013

(54) SYSTEM AND METHOD FOR PROVIDING IMPROVED IMPEDANCE MATCHING TO RF POWER TRANSISTOR USING SHUNT INDUCTANCE

(71) Applicant: William K. Veitschegger, Folsom, CA (US)

(72) Inventor: William K. Veitschegger, Folsom, CA (US)

(73) Assignee: INTEGRA TECHNOLOGIES, INC., El Segundo, CA (US)

(21) Appl. No.: 13/223,196

(22) Filed: Aug. 31, 2011

(51) Int. Cl. H03F 3/04

(52) U.S. Cl. 330/307

(57) ABSTRACT

This disclosure relates to a packaged radio frequency (RF) power transistor that includes an internal input impedance matching circuit adapted to achieve an impedance at the input lead of the package substantially higher at the input terminal of a RF power device. In particular, the internal input impedance matching circuit includes an inductive element coupled in series with a resistive element between the input terminal of the RF power device and ground. The inductance element is adapted to counter the inherent capacitance at the input terminal of the RF power device in order to substantially increase the effective input impedance of the device. The resistive element is adapted to reduce the variation of the effective input impedance of the RF power device in order provide acceptable input impedance matching across wider frequency bandwidths.

### FIELD

This invention relates generally to radio frequency (RF) circuits, and in particular, to a system and method for providing improved impedance matching to a radio frequency (RF) power transistor using shunt inductance.

### BACKGROUND

Radio frequency (RF) power amplifiers typically use active devices, such as field effect transistors (FET) and bipolar junction transistors (BJT), to perform the amplification of signals. These devices are each typically comprised of a plurality of amplification cells coupled in parallel between input and output terminals. Due to the paralleling of many amplification cells, these devices are generally capable of handling relatively large power signal levels.

One drawback of paralleling many amplification cells in such RF power devices is that their input impedance is relatively small. For example, such RF power devices may have an input impedance from a fraction of an Ohm to about a few Ohms. Usually, these devices have to interface with an input system that has a characteristic impedance much higher than a few Ohms, such as 50 Ohms. Thus, typically input impedance matching circuits are employed to improve the impedance matching between the input impedances of such RF power devices and such input systems in order to reduce signal loss (e.g., return loss) due to impedance mismatch.

The capability of these input impedance matching circuits to improve the impedance matching between input systems and the input of such RF power devices generally depends on the impedance disparity. If such RF power devices were to be designed with much higher input impedances, many benefits may be achieved. For instance, the input impedance matching may be improved. The design requirements, and thus, complexity of input impedance matching circuits may be reduced. And, such input impedance matching circuits may even be eliminated. Accordingly, the disclosure relates to a packaged RF power transistor configured to achieve higher input impedance in order to improve impedance matching with other circuits.

### SUMMARY

An aspect of the disclosure relates to a packaged radio frequency (RF) power transistor that comprises an internal input impedance matching circuit adapted to achieve a higher impedance at the input lead of the package than at the input terminal of the RF power device. In particular, the internal input matching circuit comprises an inductive element coupled in series with a resistive element between the input terminal of the RF power device and RF and/or DC ground. The inductance element is adapted to counter the inherent high capacitance at the input terminal of the RF power device in order to substantially increase the effective input impedance of the device. The resistive element is adapted to reduce the variation of the effective input impedance of the RF power device in order provide acceptable input impedance matching over wider bandwidths.

Other aspects of the disclosure relates to variations of the packaged RF power transistor described above. For instance, if the packaged RF transistor is to be used in relatively narrow bandwidth applications, the resistive element of the internal input impedance matching circuit may be eliminated. Also, if the input terminal of the RF power device requires a bias voltage, the internal input impedance matching circuit may further comprise a DC blocking capacitor situated between the inductive and/or resistive elements and DC ground. Further, components (e.g., inductive, resistive and capacitive elements) of the internal input impedance matching circuit may be discrete elements separate from the RF power device chip (die). Alternatively, any number of these components may be integrated into the RF power device chip.

Other aspects, advantages and novel features of the present disclosure will become apparent from the following detailed description when considered in conjunction with the accompanying drawings.

### BRIEF DESCRIPTION OF THE DRAWINGS

FIG. 1 illustrates a block/schematic diagram of an exemplary RF amplifier in accordance with an aspect of the disclosure.

FIG. 2A illustrates a block/schematic diagram of another exemplary RF amplifier in accordance with another aspect of the disclosure.

FIG. 2B illustrates a block/schematic diagram of yet another exemplary RF amplifier in accordance with another aspect of the disclosure.

FIG. 2C illustrates a block/schematic diagram of still another exemplary RF amplifier in accordance with another aspect of the disclosure.

FIG. 3 illustrates a top view of an exemplary RF packaged transistor in accordance with another aspect of the disclosure.

FIG. 4 illustrates a top view of another exemplary RF packaged transistor in accordance with another aspect of the disclosure.

FIG. 5 illustrates a top view of yet another exemplary RF packaged transistor in accordance with another aspect of the disclosure.

FIG. 6 illustrates a top view of still another exemplary RF packaged transistor in accordance with another aspect of the disclosure.

FIG. 7 illustrates a top view of an additional exemplary RF packaged transistor in accordance with another aspect of the disclosure.

### DETAILED DESCRIPTION OF THE EXEMPLARY EMBODIMENTS

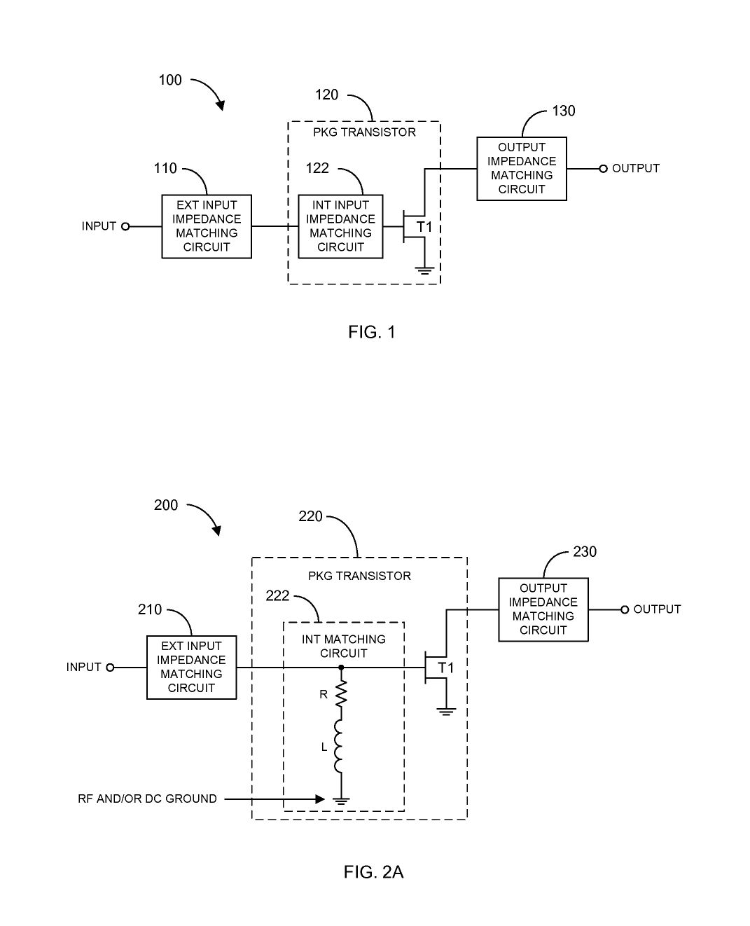

FIG. 1 illustrates a block/schematic diagram of an exemplary RF amplifier 100 in accordance with an aspect of the disclosure. In summary, the RF amplifier 100 comprises a packaged transistor that includes an RF amplification device chip (e.g., a transistor chip, such as a FET or bipolar chip) and an internal input impedance matching circuit. The internal input impedance matching is adapted to achieve an impedance at the input of the packaged transistor that is much higher than the uncorrected input impedance of the RF amplification device chip. As discussed above, this has many benefits including improving the overall input impedance matching, reducing the design requirements and complexity of an external input impedance matching circuit, and, if configured properly, completely eliminating the need for the external input impedance matching circuit.

More specifically, the RF amplifier 100 comprises an external input impedance matching circuit 110, a packaged transistor 120, and an output impedance matching circuit 130. The packaged transistor 120, in turn, comprises an internal input impedance matching circuit 122 and an RF amplification device chip T1. In this example, the RF amplification device T1 is configured as a FET. It shall be understood that other devices may be employed, such as a bipolar device, or any variations of either type, including, but not limited to, laterally diffused metal oxide semiconductor (LDMOS), Gallium-Arsenide (GaAs) FET, and others.

The internal input impedance matching circuit 122 is adapted to achieve a higher impedance at the input of the packaged transistor 120 than the uncorrected or inherent impedance at the input of the RF transistor chip T1. As an example, the internal impedance matching circuit 122 may be configured to transform an impedance of three (3) to four (4) Ohms to about 50 Ohms. In such a case, the need for the external input impedance matching circuit 110 may be eliminated. Otherwise, the external input impedance matching circuit 110 may be adapted to improve the impedance matching between the input of the RF amplifier 100 (which may have an impedance of 50 Ohms), and the input of the packaged transistor 120. Similarly, the output impedance matching circuit 130 is adapted to improve the impedance matching between the output of the packaged transistor 120 and the output of the RF amplifier 100 (which may also have an impedance of 50 Ohms).

As previously discussed above, the inclusion of the internal input impedance matching circuit has many benefits, such as improving the overall input impedance matching of the RF amplifier 100, reducing the design requirements and complexity of the external input impedance matching circuit 110, and if the internal input impedance matching circuit 122 is configured to produce a sufficiently high impedance, the need for the external input impedance matching circuit 110 may be eliminated. Described below are several exemplary implementations of the internal input impedance matching circuit 110.

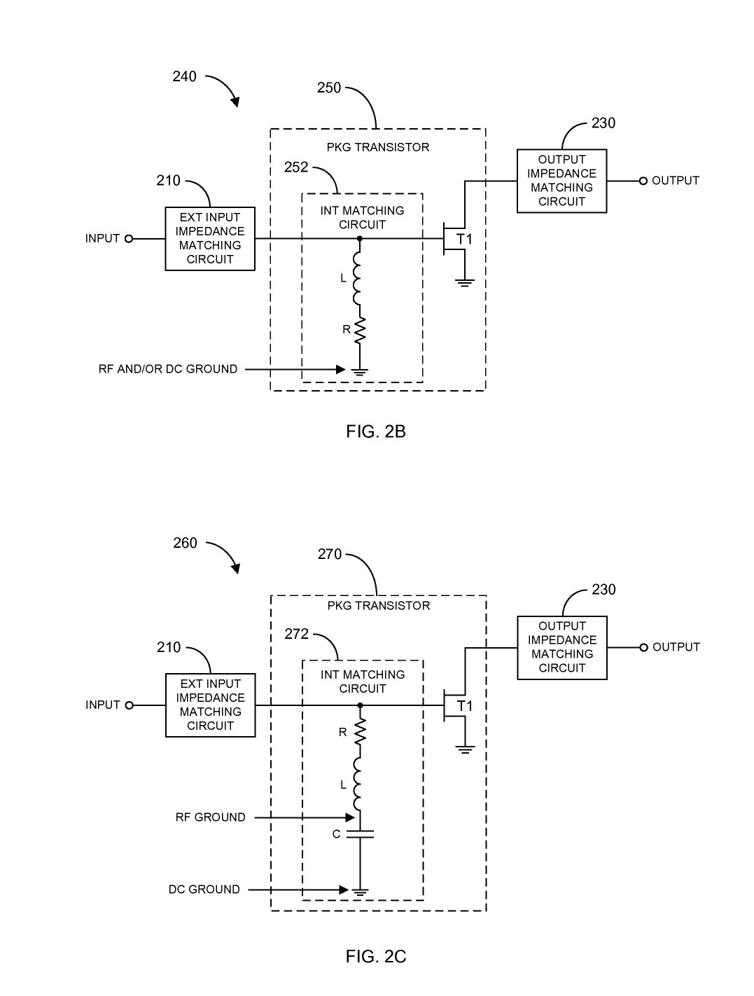

FIG. 2A illustrates a block/schematic diagram of another exemplary RF amplifier 200 in accordance with another aspect of the disclosure. The RF amplifier 200 is similar to the previous embodiment 100, but includes a more detailed exemplary implementation of the internal input impedance matching circuit.

In particular, the RF amplifier 200 comprises an external input impedance matching circuit 210, a packaged transistor 220, and an external output impedance matching circuit 230. The packaged transistor 220, in turn, comprises an internal input impedance matching circuit 222 and an RF amplification device chip T1. As in the previous embodiment, the RF amplification device chip T1 is exemplified as a FET. However, it shall be understood that other devices may be employed, as previously discussed.

In this exemplary embodiment, the internal impedance matching circuit 222 comprises a resistive element R (e.g., a resistor) and an inductive element L (e.g., an inductor). The resistive element R and inductive element L are coupled in series between an input terminal (e.g., gate) of the RF transistor chip T1 and an RF and/or DC ground terminal. The inductive element L has the effect of significantly raising the input impedance of the RF transistor chip T1 by countering the inherent high capacitance at its input terminal. The resistive element R is adapted to reduce the variation of the impedance across a specified bandwidth. Thus, by properly selecting the inductance and resistance of the inductive and resistive elements L and R, the internal impedance matching circuit 222 may be configured to provide improved impedance matching over a specified bandwidth.

It shall be understood that for relatively narrow bandwidth applications, the resistive element R may be eliminated. Thus, in such a case, the inductive element L may be connected between the input terminal of the RF transistor chip T1 and RF and/or DC ground. As discussed in more detail below, if the input terminal (e.g., gate) of the RF transistor chip T1 requires a bias voltage, a DC blocking capacitor may be connected between the resistive and inductive elements and DC ground. If, on the other hand, no bias voltage or ground is required for the input terminal of the RF transistor chip T1, the DC blocking capacitor need not be employed.

FIG. 2B illustrates a block/schematic diagram of yet another exemplary RF amplifier 240 in accordance with another aspect of the disclosure. The RF amplifier 240 is similar to that of the previous embodiment 200, but with a packaged transistor 250 comprising a modified internal input impedance matching circuit 252. More specifically, the modified internal impedance matching circuit 252 merely switches the position of the resistive and inductive elements R and L relative to each other. That is, the order of the elements from the input terminal of the RF transistor chip T1 to the RF and/or DC ground is the inductive element L followed by the resistive element R, as opposed to the opposite order as indicated with respect to the embodiment of FIG. 2A. It shall be understood that the resistive and inductive elements may be serially connected in any manner between the input terminal of the RF transistor chip T1 and RF and/or DC ground.

FIG. 2C illustrates a block/schematic diagram of still another exemplary RF amplifier 260 in accordance with another aspect of the disclosure. The RF amplifier 260 is similar to that of previous embodiment 200, but with a packaged transistor 270 comprising a modified internal input impedance matching circuit 272. More specifically, the modified internal input impedance matching circuit 272 comprises a DC blocking capacitor C coupled between the serially-connected resistive R and inductive L elements and DC ground. The DC blocking capacitor C effectively provides the RF ground on the side of the serially-connected resistive R and inductive L elements opposite the input terminal of the RF transistor chip T1. The DC blocking capacitor allows a bias voltage to be applied to the input terminal of the RF transistor chip T1 without substantially affecting the RF operation of the internal input impedance matching circuit 272.

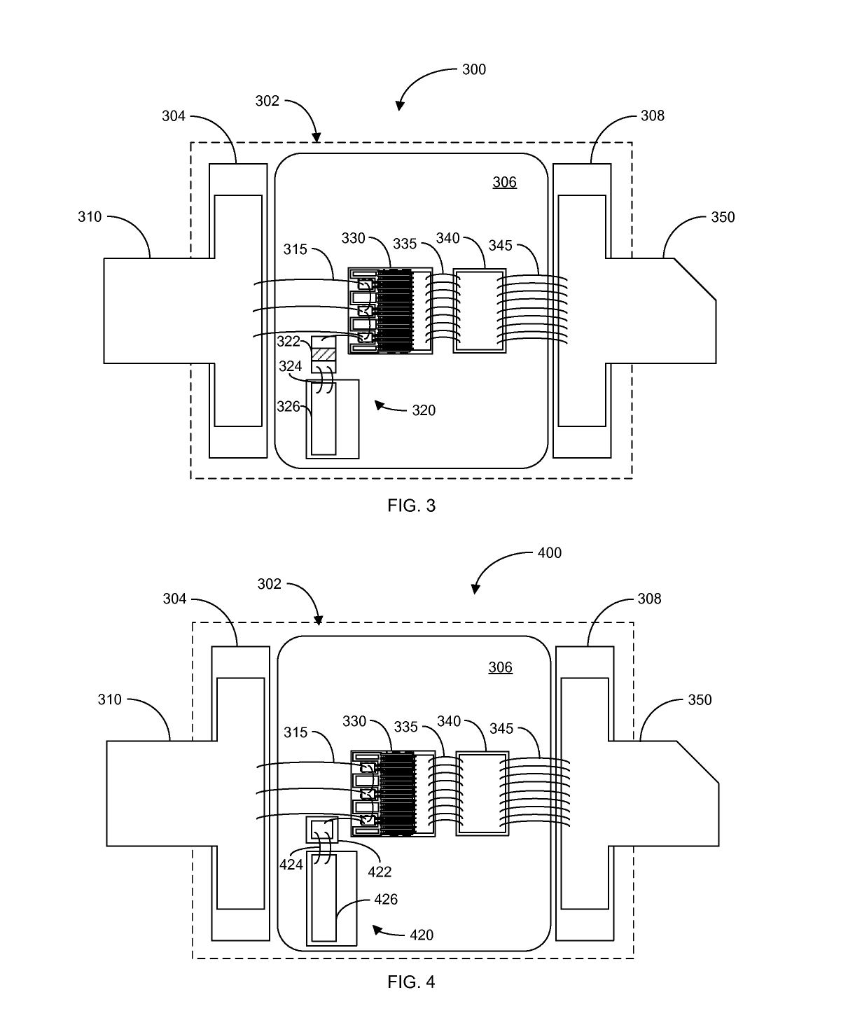

FIG. 3 illustrates a top view of an exemplary RF packaged transistor 300 in accordance with another aspect of the disclosure. The RF packaged transistor 300 is merely one example of a physical implementation of any of the RF packaged transistors previously discussed. In particular, the RF packaged transistor 300 comprises a transistor package housing 302, input lead 310, an input lead dielectric support 304, an output lead 350, an output lead dielectric support 308, and a grounded base plate 306. Both the input and output leads are mechanically coupled to the housing 302, and both respectively extend from outside to inside of the housing as illustrated.

The RF packaged transistor 300 further comprises a transistor chip 330 disposed on the grounded base plate 306, and a first set of parallel wirebonds 315 electrically coupling the input lead 310 to an input terminal (e.g., gate) of the transistor chip 330. The RF packaged transistor 300 further comprises a second set of parallel wirebonds 335 electrically coupling an output terminal (e.g., drain) of the transistor chip 330 to a bridge element 340 disposed on the grounded base plate 306, and a third set of parallel wirebonds 345 electrically coupling the bridge element 340 to the output lead 350. The bridge element 340 may comprise a dielectric substrate, a top metallization layer to which the second and third sets of wirebonds are attached, and a bottom metallization layer attached to the grounded base plate 306. Although in this example the bridge element 340 facilitates the electrical connection of the output terminal of the transistor chip 330 to the output lead 350, it shall be understood that such connection may be effectuated in many distinct manners, including directly connecting the output terminal of the transistor chip 330 to the output lead 350.

The RF packaged transistor 300 further comprises an internal input impedance matching circuit 320. In this example, the internal input impedance matching circuit 320 comprises a chip resistor 322, an inductive element 324 in the form of one or more parallel wirebonds, and a DC blocking capacitor 326. The chip resistor 322 includes a first terminal electrically coupled to the input terminal of the transistor chip 330 via one or more wirebonds. The one or more parallel wirebonds serving as the inductive element 324 electrically couple a second terminal of the chip resistor 322 to a first terminal of the DC blocking capacitor 326. The DC blocking capacitor 326 includes a second terminal electrically coupled to the grounded base plate 306. The DC blocking capacitor 326 may be configured as a silicon metal oxide semiconductor (MOS), silicon metal insulator metal (MIM), or ceramic MIM component. As previously discussed, the internal input impedance matching circuit 320 is adapted to improve the impedance matching to the input of the RF packaged transistor 300.

FIG. 4 illustrates a top view of another exemplary RF packaged transistor 400 in accordance with another aspect of the disclosure. The RF packaged transistor 400 is similar to the previous embodiment 300 and includes some of the same elements as indicated by the same reference numbers. The RF packaged transistor 400 differs from the previous embodiment 300 in that it comprises a different internal input impedance matching circuit 420. In particular, the internal input impedance matching circuit 420 does not include the chip resistor provided for in the previous embodiment.

More specifically, the internal input impedance matching circuit 420 comprises a bridge element 422, an inductive element 424 in the form of one or more parallel wirebonds, and a DC blocking capacitor 426. The bridge element 422 is electrically coupled to the input terminal of the transistor chip 330 via one or more wirebonds. The one or more parallel wirebonds serving as the inductive element 424 electrically couple the bridge element 422 to a first terminal of the DC blocking capacitor 426. The DC blocking capacitor 426 includes a second terminal electrically coupled to the grounded base plate 306. Due to the lack of the chip resistor, the internal input impedance matching circuit 420 may provide the required impedance matching for a relatively narrow bandwidth.

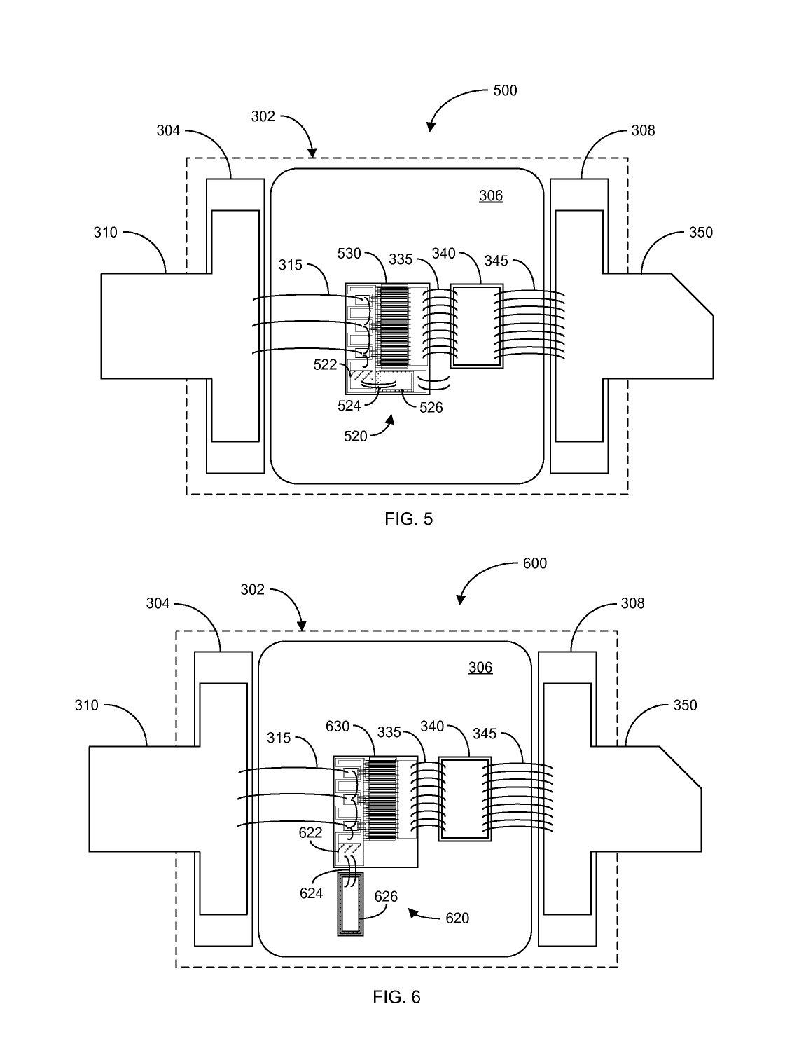

FIG. 5 illustrates a top view of yet another exemplary RF packaged transistor 500 in accordance with another aspect of the disclosure. The RF packaged transistor 500 is similar to the previous embodiments 300 and 400, and includes some of the same elements as indicated by the same reference numbers. The RF packaged transistor 500 differs from the previous embodiments in that it comprises a transistor chip 530 that includes a partially-integrated internal input impedance matching circuit 520.

More specifically, the internal input impedance matching circuit 520 comprises a thin-film resistor 522 and DC blocking capacitor 526 integrated into the transistor chip 530. The internal input impedance matching circuit 520 further comprises an inductive element 524 in the form of one or more parallel wirebonds. The thin-film resistor 522 includes a first end electrically coupled to the input of the transistor chip 530 via integrated metallization. The one or more parallel wirebonds of the inductive element 524 electrically couple a second end of the thin-film resistor 522 to a first end of the DC blocking capacitor 526. One or more parallel wirebonds electrically couple a second end of the DC blocking capacitor 526 to the grounded base plate 306. As illustrated by this embodiment, one or more components of the internal input impedance matching circuit 520 may be integrated into the transistor chip 530.

FIG. 6 illustrates a top view of still another exemplary RF packaged transistor 600 in accordance with another aspect of the disclosure. The RF packaged transistor 600 is similar to the previous embodiment 500, and includes some of the same elements as indicated by the same reference numbers. The RF packaged transistor 600 differs from the previous embodiment in that only the resistive element of an internal input impedance matching circuit is integrated into a transistor chip 630.

More specifically, the internal input impedance matching circuit 620 comprises a thin-film resistor 622 integrated into the transistor chip 630. The internal input impedance matching circuit 620 further comprises an inductive element 624 in the form of one or more parallel wirebonds, and a DC blocking capacitor 626 in the form of a MIM, MOS or ceramic MIM, for example. The thin-film resistor 622 includes a first end electrically coupled to the input of the transistor chip 630 via integrated metallization. The one or more parallel wirebonds of the inductive element 624 electrically couple a second end of the thin-film resistor 622 to a first end of the DC blocking capacitor 626. A second or bottom end of the DC blocking capacitor 626 is electrically coupled to the grounded base plate 306. Similarly, this embodiment illustrates that any number of components of the internal input impedance matching circuit 620 may be integrated into the transistor chip 630.

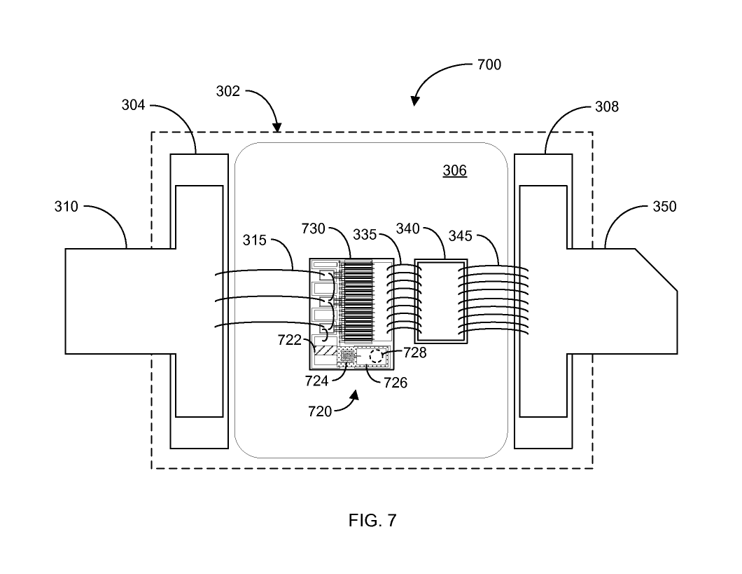

FIG. 7 illustrates a top view of an additional exemplary RF packaged transistor 700 in accordance with another aspect of the disclosure. The RF packaged transistor 700 is similar to the embodiment 500, and includes some of the same elements as indicated by the same reference numbers. The RF packaged transistor 700 differs from the embodiment 500 in that all of the elements of an internal input impedance matching circuit is integrated into a transistor chip 730.

More specifically, the internal input impedance matching circuit 720 comprises a thin-film resistor 722, inductive element 724 (e.g., spiral inductor), and DC blocking capacitor 726, all integrated into the transistor chip 730. The thin-film resistor 622 includes a first end electrically coupled to the input of the transistor chip 630 via integrated metallization. A first end of the inductive element 724 is electrically coupled to a second end of the thin-film resistor 722 via integrated metallization. A first end of the DC blocking capacitor 726 is electrically coupled to a second end of the inductive element 724 via integrated metallization. A second end of the DC blocking capacitor 726 is electrically coupled to the grounded base plate 306 by way of a metalized via hole 728 formed through the transistor chip 730. Again, as illustrated, any number of components of the internal input impedance matching circuit 720, including all, may be integrated into the transistor chip 730.

While the invention has been described in connection with various embodiments, it will be understood that the invention is capable of further modifications. This application is intended to cover any variations, uses or adaptation of the invention following, in general, the principles of the invention, and including such departures from the present disclosure as come within the known and customary practice within the art to which the invention pertains.

What is claimed is:

1. A radio frequency (RF) packaged transistor, comprising:
a housing;
an input lead mechanically coupled to the housing, and extending from outside of the housing to inside of the housing;
an output lead mechanically coupled to the housing, and extending from inside of the housing to outside of the housing;
an RF transistor chip situated inside of the housing, wherein the RF transistor chip comprises an input terminal electrically coupled to the input lead, and an output terminal electrically coupled to the output lead; and
an input impedance matching circuit situated inside of the housing, wherein the input impedance matching circuit comprises an inductive element electrically coupled to the input terminal of the RF transistor chip and a ground.

2. The RF packaged transistor of claim 1, wherein the inductive element comprises one or more wirebonds.

3. The RF packaged transistor of claim 1, wherein the inductive element is integrated into the RF transistor chip.

4. The RF packaged transistor of claim 1, wherein the input impedance matching circuit further comprises a resistive element coupled in series with the inductive element between the input terminal of the RF transistor chip and the ground.

5. The RF packaged transistor of claim 4, wherein the resistive element comprises a chip resistor.

6. The RF packaged transistor of claim 4, wherein the resistive element is integrated into the transistor chip.

7. The RF packaged transistor of claim 6, wherein the inductive element is integrated into the RF transistor chip.

8. The RF packaged transistor of claim 1, wherein the ground comprises an RF ground.

9. The RF packaged transistor of claim 1, wherein the ground comprises an RF and DC ground.

10. The RF packaged transistor of claim 1, wherein the input impedance matching circuit further comprises a DC blocking capacitor coupled between the inductive element and ground.

11. The RF packaged transistor of claim 10, wherein the DC blocking capacitor is configured as a silicon metal oxide semiconductor (MOS), a silicon metal insulator metal (MIM), or a ceramic MIM component.

12. The RF packaged transistor of claim 10, wherein the DC blocking capacitor is integrated into the RF transistor chip.

13. The RF packaged transistor of claim 12, wherein the inductive element is integrated into the RF transistor chip.

14. The RF packaged transistor of claim 13, wherein the input impedance matching circuit further comprises a resistive element coupled in series with the inductive element, and further wherein the resistive element is situated between the DC blocking capacitor and the input terminal of the RF transistor chip.

15. The RF packaged transistor of claim 14, wherein the ground comprises a DC ground, and further wherein the transistor chip comprises a metalized via hole adapted to apply the DC ground to the DC blocking capacitor.

16. A radio frequency (RF) amplifier, comprising:
an input circuit;
an output circuit; and
a packaged transistor, comprising
a housing;
an input lead mechanically coupled to the housing, and extending from outside of the housing to inside of the housing, wherein the input lead is electrically coupled to the input circuit;
an output lead mechanically coupled to the housing, and extending from inside of the housing to outside of the housing, wherein the output lead is electrically coupled to the output circuit;
an RF transistor chip situated inside of the housing, wherein the RF transistor chip comprises an input terminal electrically coupled to the input lead, and an output terminal electrically coupled to the output lead; and
an input impedance matching circuit situated inside of the housing, wherein the input impedance matching circuit comprises an inductive element electrically coupled to the input terminal of the RF transistor chip and ground.

17. The RF amplifier of claim 16, wherein the input impedance matching circuit further comprises a resistive element coupled in series with the inductive element.

18. A radio frequency (RF) amplifier, comprising:
an external output impedance matching circuit; and
a packaged transistor, comprising
a housing;
an input lead mechanically coupled to the housing, and extending from outside of the housing to inside of the housing;
an output lead mechanically coupled to the housing, and extending from inside of the housing to outside of the housing, wherein the input lead is electrically coupled to the external output impedance matching circuit;
an RF transistor chip situated inside of the housing, wherein the RF transistor chip comprises an input terminal electrically coupled to the input lead, and an output terminal electrically coupled to the output lead; and
an input impedance matching circuit situated inside of the housing, wherein the input impedance matching circuit comprises an inductive element electrically coupled to the input terminal of the RF transistor chip and ground.

19. The RF amplifier of claim 18, wherein the input impedance matching circuit further comprises a resistive element coupled in series with the inductive element.

20. The RF amplifier of claim 18, further comprising an external input impedance matching circuit, wherein the input lead of the packaged transistor is electrically coupled to the external input impedance matching circuit.
